(19) United States
(12) Patent Application Publication
(10) Pub. No.: US 2008/0149174 A1
(43) Pub. Date: Jun. 26, 2008

(54) Polymer solar cell and manufacturing method thereof

(76) Inventors: Fang-Chung Chen, Jhushan Township (TW); Chih-Wei Chu, Taipei City (TW); Chu-Jung Ko, Taipei City (TW); Yi-Kai Lin, Ji-an Township (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/802,436

(22) Filed: May 23, 2007

(30) Foreign Application Priority Data
Dec. 26, 2006 (TW) 095149006

(51) Int. Cl. H01L 31/06

(52) U.S. Cl. 136/255; 977/752

(57) ABSTRACT

A polymer solar cell and a manufacturing method thereof are disclosed. The cell includes a substrate, a first electrode located on top of the substrate, a conductive polymer layer having a conductive polymer and an additive located on the first electrode, a semiconductor layer over the conductive polymer layer and a second electrode over the semiconductor layer. The manufacturing method of the polymer solar cell is composed of following steps: growing a first electrode on a substrate; mixing an additive and a conductive polymer to form a mixture; depositing the mixture on the first electrode to form a conductive polymer layer; depositing a semiconductor layer on the conductive polymer layer and evaporating a second electrode on the semiconductor layer. By adding additive into the conductive polymer, resistance of the conductive polymer layer is reduced and efficiency of the cell is improved.

### BACKGROUND OF THE INVENTION

The present invention relates to a solar cell and a manufacturing method thereof, especially to a polymer solar cell and a manufacturing method thereof. The polymer solar cell includes a conductive polymer layer having conductive polymer such as 3,4-polyethylenedioxythiophene-polystyrenesulfonate (PEDOT:PSS) as well as additive such as mannitol that reduces resistance of the conductive polymer layer and improves working efficiency of the solar cell.

In earlier days, (poly(3,4-ethylenedioxythiophene):poly (styrenesulfonate) (PEDOT:PSS) is the most broadly used conductive polymer due to good thermal stability and high conductivity. Moreover, it's transparent in visible light area so that it's applied to some organic optoelectronics component. In about 2000, several ways that increase conductivity of PEDOT:PSS available on market are found. For example, change of the chemical structure, addition of various organic solvent or surfactants, and doapnt-addition of “OH” group can all increase conductivity of PEDOT:PSS [J. Huang et. al Adv. Funct. Mat. 15, 290 (2005)]. A lot of research is trying to use such high-conductive PEDOT:PSS to replace indium-tin-oxide(ITO) glass. For example, in 2002, W. H. Kim et al. add glycerol in PEDOT:PSS so as to get conductive polymer with low resistance and high transparency. Such conductive polymer can replace organic light-emitting diodes (OLED) made from ITO [W. H. Kim et al. Appl. Phys. Lett. 80, 3844 (2002)]. In the same year, M. K. Fung et al. add glycerol into PEDOT:PSS for general polymer light-emitting diodes so as to make PEDOT:PSS allow higher current to pass. The efficiency of the polymer light-emitting diodes is increased from 1.3 cd/A to 1.7 cd /A [M. K. Fung et al. Appl. Phys. Lett. 81, 1497 (2002)].

In laboratories that study organic solar cells with efficiency of nearly 5%, professor A. J. Heeger of UC Santa Barbara is a representative. A team lead by professor A. J. Heeger achieves 5.1% energy conversion efficiency by post-annealing [W. Ma et al. Adv. Funct. Mater. 15, 1617 (2005)]. Such outstanding research focuses on organic semiconductor layer without consideration of an important factor-resistance of conductive polymer layer essential for the solar cell. The resistance affects efficiency of the whole solar cell. Therefore, by reducing resistance of PEDOT:PSS, the present invention improve energy conversion efficiency of the solar energy cell.

### SUMMARY OF THE INVENTION

It is therefore a primary object of the present invention to provide a polymer solar cell and a manufacturing method thereof. The polymer solar cell includes a conductive polymer such as PEDOT:PSS as well as additive such as mannitol that reduces resistance of the conductive polymer layer.

It is another object of the present invention to provide a polymer solar cell and a manufacturing method thereof. The polymer solar cell includes a conductive polymer such as PEDOT:PSS as well as additive such as mannitol so as to increase current and conversion efficiency of the solar cell.

In order to achieve above objects, the present invention provides a polymer solar cell and a manufacturing method thereof. The polymer solar cell includes a substrate, a first electrode located on top of the substrate, a conductive polymer layer having a conductive polymer and an additive on the first electrode, a semiconductor layer over the conductive polymer layer and a second electrode over the semiconductor layer. The manufacturing method of the polymer solar cell consists of following steps: growing a first electrode on a substrate; mixing an additive and a conductive polymer to form a mixture; depositing the mixture on the first electrode to form a conductive polymer layer; depositing a semiconductor layer on the conductive polymer layer and evaporating a second electrode on the semiconductor layer. Therefore, a polymer solar cell is obtained.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein

FIG. 1 is a schematic drawing of a polymer solar cell according to the present invention;

FIG. 2 is a schematic drawing showing a semiconductor layer of the polymer solar cell according to the present invention;

FIG. 3 is a schematic drawing showing a semiconductor layer of the polymer solar cell according to the present invention;

FIG. 4 is a schematic drawing showing a semiconductor layer of the polymer solar cell according to the present invention;

FIG. 5 is a schematic drawing showing a semiconductor layer of the polymer solar cell according to the present invention;

FIG. 6 is a flow chart of a manufacturing method of a polymer solar cell according to the present invention;

FIG. 7 shows chemical structure of PEDOT:PSS of an embodiment according to the present invention;

FIG. 8 shows chemical structure of mannitol of an embodiment according to the present invention;

FIG. 9 shows chemical structure of P3HT of an embodiment according to the present invention;

FIG. 10 shows chemical structure of PCBM of an embodiment according to the present invention;

FIG. 11 is a schematic drawing showing a polymer solar cell of an embodiment according to the present invention;

FIG. 12 is a current density versus voltage figure showing curve of an embodiment having a conductive polymer layer formed by PEDOT:PSS as well as 9 wt % mannitol and curve of an embodiment having a conductive polymer layer formed by pure PEDOT:PSS according to the present invention under 100 mW/cm² AM1.5G light.

### DETAILED DESCRIPTION OF THE PREFERRED EMBODIMENT

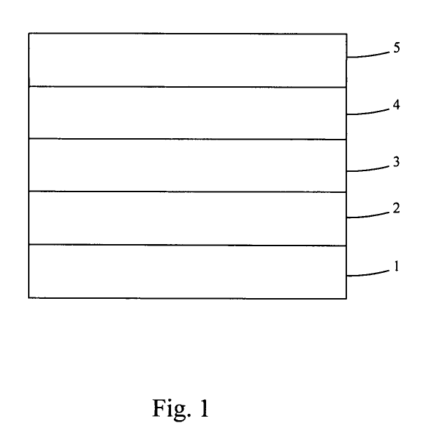

Refer to FIG. 1, a polymer solar cell according to the present invention includes a substrate 1, a first electrode 2 located on top of the substrate 1, a conductive polymer layer 3 having a conductive polymer and an additive, a semiconductor layer 4 over the conductive polymer layer 3 and a second electrode 5 over the semiconductor layer 4. The additive is selected from mannitol, sorbitol, N-methylpyrrolidone, isopropanol, dimethyl sulfoxide, N,N-dimethylformamide, tetrahydrofuran, surfactants, or combinations of them.

The substrate 1 is selected from one of a glass substrate, a polymer plastic substrate and an electronic circuit board. The electronic circuit board is a silicon substrate while the polymer plastic substrate is made from polyethylene teraphthalate (PET) and polycarbonate.

The first electrode 2 is selected from transparent conductor group or semitransparent conductor group. The transparent conductor group includes indium tin oxide (ITO) and indium-zinc-oxide (IZO) while the semitransparent conductor is a metal film made of silver, aluminum, titanium, nickel, copper, gold or chromium.

The conductive polymer on the conductive polymer layer 3 is selected from one of the followings:

3,4-polyethylenedioxythiophene-polystyrenesulfonate (PEDOT:PSS), polyaniline, polypyrrole and polyacetylene. The additive is a surfactant such as poly[oxyethylene tridecyl ether].

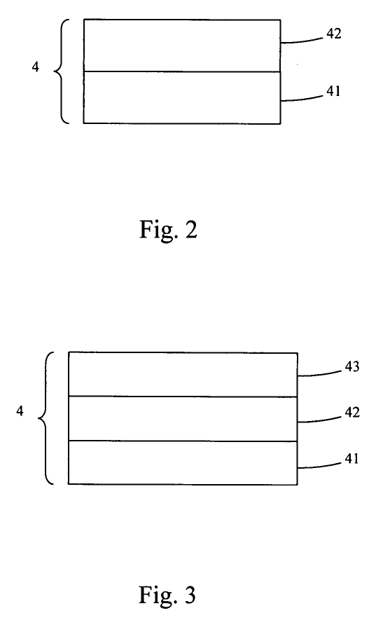

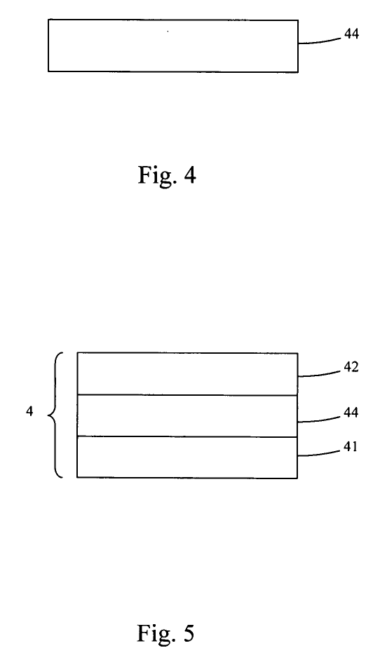

The semiconductor layer 4 is a combination of a p-type semiconductor layer 41 and a n-type semiconductor layer 42, as shown in FIG. 2. The semiconductor layer 4 can also be composed of a buffer layer 43, a p-type semiconductor layer 41 and a n-type semiconductor layer 42, or a mixing layer of the p-type semiconductor and the n-type semiconductor 44, as shown in FIG. 4. Or the semiconductor layer 4 is composed of a mixing layer of the p-type semiconductor and the n-type semiconductor 44, a p-type semiconductor layer 41 and a n-type semiconductor layer 42, as shown in FIG. 5. The p-type semiconductor layer 41 is made of polythiophene, polyfluorene, polyphenylenevinylene, polythiophene derivatives, polyfluorene derivatives, polyphenylenevinylene derivatives, conjugated oligomers or small molecules. The polythiophene derivative is poly(3-hexylthiophene)(P3HT). The polyfluorene derivative is poly(dioctylfluorene). The polyphenylenevinylene derivative is poly[2-methoxy-5-(2-ethyl-hexyloxy)-1,4-phenylene vinylene]. The conjugated oligomer is sexithiophene. The small molecule is selected from one of the followings: pentacene, tetracene, hexabenzcoronene, phthalocyanine, porphyrines, pentacene derivatives, tetracene derivatives, hexabenzcoronene derivatives, phthalocyanine derivatives, and porphyrines derivatives.

Materials for making the n-type semiconductor layer 42 is selected from one of the followings: C₆₀, C₆₀ derivatives, C₇₀, C₇₀ derivatives, carbon nanotubes, derivatives of carbon nanotubes, 3,4,9,10-perylene (tetracarboxylic-bis-benzimidazole, PTCBI), N, N′-dimethyl-3,4,9,10-Perylenetetracarboxylic acid diimide (Me-PTCDI), derivatives of 3,4,9,10-perylene (tetracarboxylic-bis-benzimidazole, PTCBI), derivatives of N,N′-dimethyl-3,4,9,10-Perylenetetracarboxylic acid diimide (Me-PTCDI), polymers and semiconductor nanoparticles. The C₆₀ derivative is phenyl C61-butyric acid methyl ester (PCBM) and the polymer is poly(2,5,2′,5′-tetrahexyloxy-7,8′-dicyano-di-p-phenylenevinylene (CN-PPV) or poly(9,9′-dioctylfluorene-co-benzothiadiazole (F8BT). The carbon nanotubes are made of Multi-walled carbon nanotubes or single wall carbon nanotube while the diameter of cross section of the carbon nanotube is less than 100 nm. The semiconductor nanoparticle is made of titanium oxide, cadmium selenide or cadmium sulphide.

The second electrode 5 can be a single-layer structure or a double-layer structure. The single layer structure is made of magnesium gold alloy while the double-layer structure is made of lithium fluoride (LiF/Al) or calcium/aluminum (Ca/Al). The first electrode 2 pattern can be the same or different from that of the conductive polymer layer 3. The pattern of the first electrode 2 is a netty structure or others.

The additive is mannitol and the conductive polymer is PEDOT:PSS. The weight ratio of the mannitol/(PEDOT:PSS ranges from 1:99 to 9:91, 9:91 is preferably. The semiconductor layer is a mixing layer of P3HT and PCBM. The weight ratio of P3HT to PCBM is between 1˜1.25 while 1 is preferably. The second electrode includes a calcium layer and an aluminum layer and the calcium layer is deposited on the semiconductor layer while the aluminum layer is a protective layer of the calcium layer.

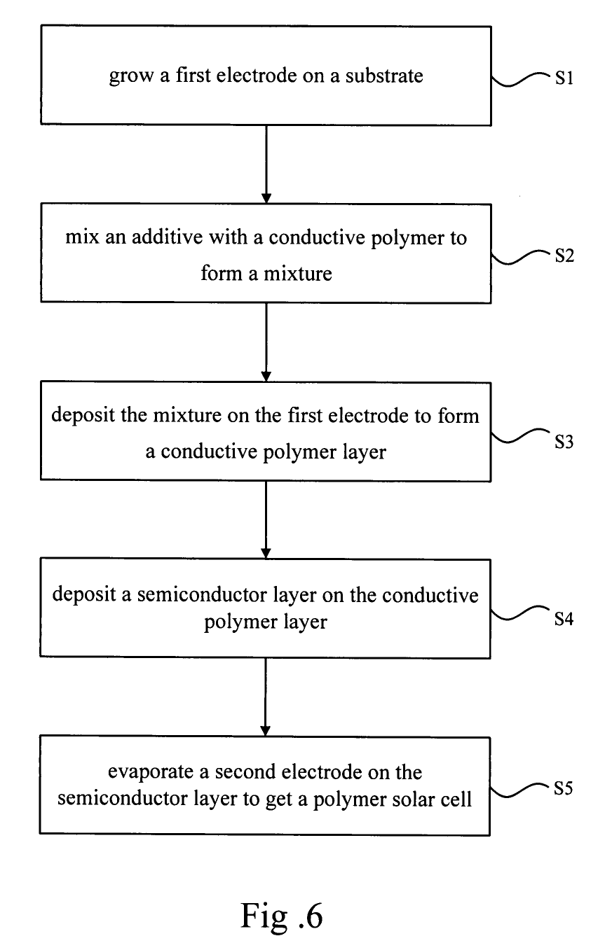

Refer to FIG. 6, a manufacturing method of the polymer solar cell is composed of following steps:

### S1 grow a first electrode on a substrate;

### S2 mix an additive with a conductive polymer to form a mixture;

### S3 deposit the mixture on the first electrode to form a conductive polymer layer

### S4 deposit a semiconductor layer on the conductive polymer layer; and

### S5 evaporate a second electrode on the semiconductor layer to get a polymer solar cell.

After the step S2 a mixture is formed, the method further including a first heating step and a step of cooling down to the room temperature. In the first heating step, the preferable temperature is 140□ and the preferable time is one hour.

After the step S4, deposit a semiconductor layer on the conductive polymer layer, the method further includes a step of volatilizing the solvent and this step takes 5 minutes to 30 hours while 10 hours are preferable. After the step of volatilizing the solvent, the method further includes a second heating step, the preferable temperature of this step is larger than 100° C. and the preferable time is 15 minutes.

In the step of S2 mixing an additive with a conductive polymer to form a mixture, the additive is mannitol and the conductive polymer is PEDOT:PSS. The weight ratio of the mannitol to PEDOT:PSS ranges from 1:99 to 9:91 while the preferable weight ratio is 9:91.

In the step of S3 depositing the mixture on the first electrode to form a conductive polymer layer, the way of deposit consists of spin-coating, dip coating, drop casting, doctor blading, inkjet printing, screen printing, or others.

In the step of S4, depositing a semiconductor layer on the conductive polymer layer, the semiconductor layer is a mixture of P3HT and PCBM while the weight ratio of P3HT to PCBM is from 1 to 1.25 and the preferable ratio is 1.

In the step of S5 evaporating a second electrode on the semiconductor layer to get a polymer solar cell, the second electrode includes a calcium layer and an aluminum layer and the calcium layer is deposited on the semiconductor layer while the aluminum layer is a protective layer of the calcium layer.

### An Embodiment

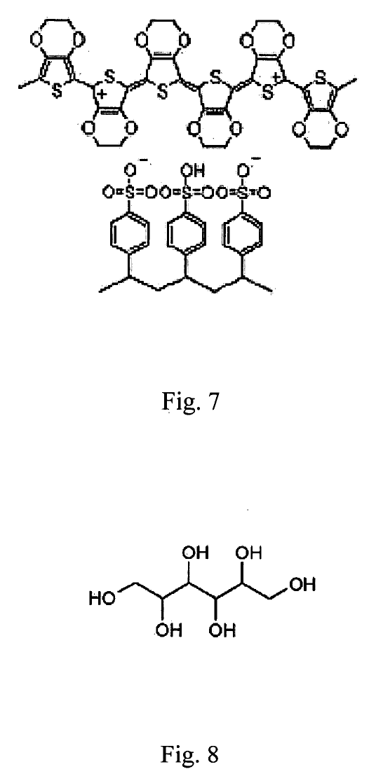

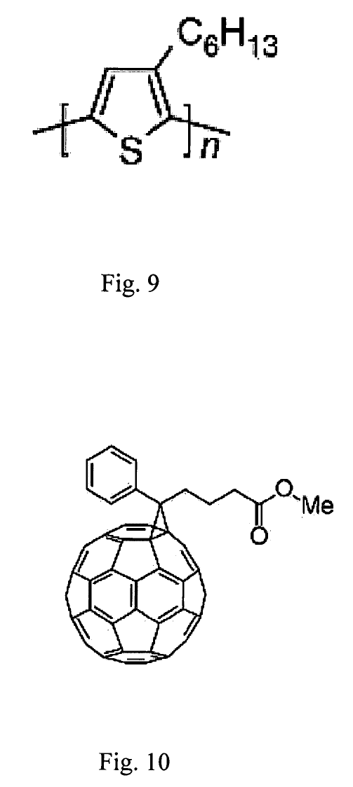

In the beginning, add mannitol (chemical structure is shown in FIG. 8) into PEDOT:PSS (chemical structure is shown in FIG. 7) while weight ratio of the PEDOT:PSS to mannitol is 9:91, working as material for a conductive polymer layer. The semiconductor layer is made of mixture of P3HT (chemical structure is shown in FIG. 9) and PCBM (chemical structure is shown in FIG. 10) while weight ratio of P3HT to PCBM is 1:1.

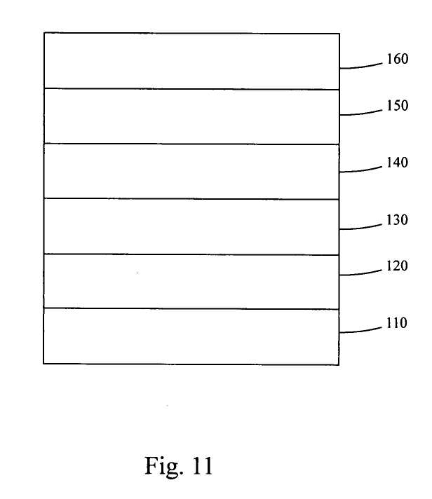

An indium tin oxide film 120 is grown on a substrate 110. Then a conductive polymer layer 130 is coated on the indium tin oxide film 120. In this embodiment, the conductive polymer layer 130 is made of PEDOT:PSS added with mannitol. Then heat the whole film at the temperature of 140° C. for one hour and cool down to room temperature. A semiconductor layer 140 is deposited on the conductive polymer layer 130. Material for the semiconductor layer 140 is mixture of P3HT and PCBM. After being deposited by spin coating, the substrate is put inside a close incubator for 10 hours so as to evaporate solvent slowly. Next heat the substrate again at the temperature of 110° C. for 15 minutes. Then remove the substrate to an evaporation system for coat a calcium layer 150 by evaporation. For protection of the calcium layer 150, next an aluminum layer 160 is further coated thereon by evaporation. Thus a polymer solar cell of the present invention is obtained, as shown in FIG. 11.

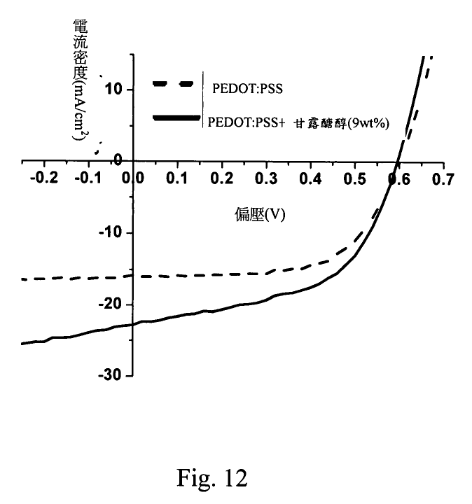

Refer to FIG. 12, a current vs voltage figure of an embodiment under 100 mW/cm² AM1.5G light is disclosed. When pure PEDOT:PSS is used, the open circuit voltage is 0.60V, short-circuit current is 16.0 mA/cm², and a fill factor is 0.64. After standard spectral-correction, the energy conversion obtained is 4.6%. After the PEDOT:PSS being added with mannitol, the open circuit voltage is 0.60V, the short-circuit current is 16.0 mA/cm², and the fill factor is 0.64 while energy conversion is increased into 5.4%.

From above results, it is obvious that conversion efficiency of the component is increased nearly 20%. For solar cells, this is a great progress. Thus such way is feasible to improve efficiency of the element. Moreover, the conversion efficiency of this method is higher than that of other methods in other articles. This show importance of the present invention.

In summary, a polymer solar cell and a manufacturing method thereof according to the present invention provide a solar cell having a conductive polymer layer composed of conductive polymer such as PEDOT:PSS and additive such as mannitol that reduces total resistance of the solar cell and increases electric current and conversion efficiency of the solar cell.

Additional advantages and modifications will readily occur to those skilled in the art. Therefore, the invention in its broader aspects is not limited to the specific details, and representative devices shown and described herein. Accordingly, various modifications may be made without departing from the spirit or scope of the general inventive concept as defined by the appended claims and their equivalents.

What is claimed is:

1. A polymer solar cell comprising:
a substrate;
a first electrode located on the substrate;
a conductive polymer layer on the first electrode and having a conductive polymer and an additive while the additive is selected from mannitol, sorbitol, N-methylpyrrolidone, isopropanol, dimethyl sulfoxide, N,N-dimethylformamide, tetrahydrofuran, surfactants, or mixture of them;
a semiconductor layer over the conductive polymer layer; and
a second electrode over the semiconductor layer.

2. The polymer solar cell as claimed in claim 1, wherein the substrate is a glass substrate, a polymer plastic substrate or an electronic circuit board.

3. The polymer solar cell as claimed in claim 2, wherein the polymer plastic substrate is made from polyethylene teraphthalate (PET) and polycarbonate.

4. The polymer solar cell as claimed in claim 2, wherein the electronic circuit board is a silicon substrate.

5. The polymer solar cell as claimed in claim 1, wherein the first electrode is made from transparent conductor or semitransparent conductor.

6. The polymer solar cell as claimed in claim 5, wherein the transparent conductor is indium tin oxide (ITO) or indium-zinc-oxide (IZO).

7. The polymer solar cell as claimed in claim 5, wherein the semitransparent conductor is a metal film made of silver, aluminum, titanium, nickel, copper, gold or chromium.

8. The polymer solar cell as claimed in claim 1, wherein the conductive polymer is 3,4-polyethylenedioxythiophene-polystyrenesulfonate (PEDOT:PSS), polyaniline, polypyrrole or polyacetylene.

9. The polymer solar cell as claimed in claim 1, wherein the surfactant is poly[oxyethylene tridecyl ether].

10. The polymer solar cell as claimed in claim 1, wherein the semiconductor layer is a combination of a p-type semiconductor layer and a n-type semiconductor layer, a buffer layer together with a p-type semiconductor layer and a n-type semiconductor layer, a mixing layer of the p-type semiconductor layer and the n-type semiconductor layer, or a mixing layer of the p-type semiconductor layer and the n-type semiconductor layer together with a combination of a p-type semiconductor layer and a n-type semiconductor layer.

11. The polymer solar cell as claimed in claim 10, wherein the p-type semiconductor layer is made of polythiophene, polyfluorene, polyphenylenevinylene, polythiophene derivatives, polyfluorene derivatives, polyphenylenevinylene derivatives, conjugated oligomers or small molecules.

12. The polymer solar cell as claimed in claim 11, wherein the polythiophene derivative is poly(3-hexylthiophene), the polyfluorene derivative is poly(dioctylfluorene) and the polyphenylenevinylene derivative is poly[2-methoxy-5-(2-ethyl-hexyloxy)-1,4-phenylene vinylene].

13. The polymer solar cell as claimed in claim 11, wherein the conjugated oligomer is sexithiophene.

14. The polymer solar cell as claimed in claim 11, wherein the small molecule is selected from one of the followings: pentacene, tetracene, hexabenzcoronene, phthalocyanine, porphyrines, pentacene derivatives, tetracene derivatives, hexabenzcoronene derivatives, phthalocyanine derivatives, and porphyrines derivatives.

15. The polymer solar cell as claimed in claim 10, wherein the n-type semiconductor layer is made from C₆₀, C₆₀ derivatives, C₇₀, C₇₀ derivatives, carbon nanotubes, derivatives of carbon nanotubes, 3,4,9,10-perylene (tetracarboxylic-bis-benzimidazole, PTCBI), N, N′-dimethyl-3,4,9,10-Perylenetetracarboxylic acid diimide (Me-PTCDI), derivatives of 3,4,9,10-perylene (tetracarboxylic-bis-benzimidazole, PTCBI), derivatives of N, N′-dimethyl-3,4,9,10-Perylenetetracarboxylic acid diimide (Me-PTCDI), polymers and semiconductor nanoparticles.

16. The polymer solar cell as claimed in claim 15, wherein the carbon nanotubes are multi-walled carbon nanotubes or single wall carbon nanotubes.

17. The polymer solar cell as claimed in claim 16, wherein diameter of cross section of the carbon nanotube is less than 100 nm. The semiconductor nanoparticle is made of titanium oxide, cadmium selenide or cadmium sulphide.

18. The polymer solar cell as claimed in claim 15, wherein the C₆₀ derivative is phenyl C61-butyric acid methyl ester (PCBM).

19. The polymer solar cell as claimed in claim 15, wherein the polymer is poly (2,5,2′,5′-tetrahexyloxy-7,8′-dicyano-di-p-phenylenevinylene (CN-PPV) or poly(9,9′-dioctylfluorene-co-benzothiadiazole (F8BT).

20. The polymer solar cell as claimed in claim 15, wherein the semiconductor nanoparticle is made of titanium oxide, cadmium selenide or cadmium sulphide.

21. The polymer solar cell as claimed in claim 1, wherein the second electrode is a single-layer structure or a double-layer structure.

22. The polymer solar cell as claimed in claim 21, wherein the single layer structure is made of magnesium gold alloy.

23. The polymer solar cell as claimed in claim 21, wherein the double-layer structure is made of lithium fluoride (LiF/Al) or calcium/aluminum (Ca/Al).

24. The polymer solar cell as claimed in claim 1, wherein pattern of the first electrode is the same or different from pattern of the conductive polymer layer.

25. The polymer solar cell as claimed in claim 1, wherein the additive is mannitol and the conductive polymer is PEDOT:PSS. The second electrode includes a calcium layer and an aluminum layer and the calcium layer is deposited on the semiconductor layer while the aluminum layer is a protective layer of the calcium layer.

26. The polymer solar cell as claimed in claim 25, wherein weight ratio of mannitol to PEDOT:PSS ranges from 1:99 to 9:91.

27. The polymer solar cell as claimed in claim 26, wherein the preferable weight ratio of mannitol/(PEDOT:PSS) is 9:91.

28. The polymer solar cell as claimed in claim 1, wherein the semiconductor layer is a mixing layer of (poly(3-hexylthiophene)(P3HT) and phenyl C61-butyric acid methyl ester (PCBM).

29. The polymer solar cell as claimed in claim 28, wherein weight ratio of P3HT to PCBM is between 1˜1.25.

30. The polymer solar cell as claimed in claim 29, wherein the preferable weight ratio of P3HT to PCBM is 1.

31. The polymer solar cell as claimed in claim 1, wherein the second electrode having a calcium layer and an aluminum layer while the calcium layer is deposited on the semiconductor layer and the aluminum layer is a protective layer of the calcium layer.

32. A manufacturing method of the polymer solar cell comprising the steps of:
growing a first electrode on a substrate;
mixing an additive with a conductive polymer to form a mixture;
depositing the mixture on the first electrode to form a conductive polymer layer;
depositing a semiconductor layer on the conductive polymer layer; and
evaporating a second electrode on the semiconductor layer to get a polymer solar cell.

33. The manufacturing method of the polymer solar cell as claimed in claim 32, wherein after the step of mixing an additive with a conductive polymer to form a mixture, the method further comprising a first heating step and a step of cooling down to the room temperature.

34. The manufacturing method of the polymer solar cell as claimed in claim 33, wherein in the first heating step, heating temperature ranges from 100° C. to 200° C. and heating time is from 5 minutes to 3 hours.

35. The manufacturing method of the polymer solar cell as claimed in claim 34, wherein in the first heating step, the preferable heating temperature is 140° C. and the preferable heating time is one hour.

36. The manufacturing method of the polymer solar cell as claimed in claim 32, wherein after the step of depositing a semiconductor layer on the conductive polymer layer, the method further comprising a step of volatilizing solvent.

37. The manufacturing method of the polymer solar cell as claimed in claim 36, wherein the step of volatilizing solvent takes 5 minutes to 30 hours.

38. The manufacturing method of the polymer solar cell as claimed in claim 37, wherein the preferable time of volatilizing solvent is 10 hours.

39. The manufacturing method of the polymer solar cell as claimed in claim 36, wherein after the step of volatilizing the solvent, the method further comprising a second heating step.

40. The manufacturing method of the polymer solar cell as claimed in claim 39, wherein temperature of the second heating step ranges from 70° C. to 200° C. and time of the second heating step is 0 minute to 10 hours.

41. The manufacturing method of the polymer solar cell as claimed in claim 40, wherein the preferable temperature of the second heating step is over 100° C. and the preferable time of the second heating step is 15 minutes.

42. The manufacturing method of the polymer solar cell as claimed in claim 32, wherein the additive is selected from mannitol, sorbitol, N-methylpyrrolidone, isopropanol, dimethyl sulfoxide, N,N-dimethylformamide, tetrahydrofuran, surfactants, or mixture of them while the conductive polymer is PEDOT:PSS.

43. The manufacturing method of the polymer solar cell as claimed in claim 42, wherein preferable weight ratio of mannitol to PEDOT:PSS is 9:91.

44. The manufacturing method of the polymer solar cell as claimed in claim 32, wherein the semiconductor layer is a mixing layer of (poly(3-hexylthiophene)(P3HT) and phenyl C61-butyric acid methyl ester (PCBM).

45. The manufacturing method of the polymer solar cell as claimed in claim 44, wherein preferable weight ratio of P3HT to PCBM is 1:1.

46. The manufacturing method of the polymer solar cell as claimed in claim 32, wherein in the step of evaporating a second electrode on the semiconductor layer to get a polymer solar cell, the second electrode comprising a calcium layer and an aluminum layer while the calcium layer is deposited on the semiconductor layer and the aluminum layer is a protective layer of the calcium layer.

47. The manufacturing method of the polymer solar cell as claimed in claim 32, wherein in the step of depositing the mixture on the first electrode to form a conductive polymer layer, the way of depositing is spin-coating, dip coating, drop casting, doctor blading, inkjet printing, or screen printing.
